(19) United States
(12) Patent Application Publication
(10) Pub. No.: US 2023/0119520 A1
(43) Pub. Date: Apr. 20, 2023

(54) DISPLAY PANEL AND METHOD FOR MANUFACTURING THEREOF

(71) Applicant: Wuhan China Star Optoelectronics Semiconductor Display Technology Co., Ltd., Wuhan (CN)

(72) Inventor: Yijia WANG, Wuhan (CN)

(21) Appl. No.: 17/267,884

(22) PCT Filed: Sep. 11, 2020
(86) PCT No.: PCT/CN2020/114742

§ 371 Date: Feb. 11, 2021

(30) Foreign Application Priority Data
Jun. 24, 2020 (CN) 202010592328.2

(51) Int. Cl. H10K 59/80; H10K 77/10; G09F 9/30

(52) U.S. Cl. CPC H10K 59/873; G09F 9/301; H10K 77/111; H10K 2102/311

(57) ABSTRACT

The present application provides a display panel and a method for manufacturing the display panel. The display panel includes a substrate, at least one raised structure, a film encapsulation layer, and a planarization layer. The raised structure is disposed on the substrate. The film encapsulation layer covers the substrate, the raised structure, and a space sidewall of the space. The planarization layer is disposed on the film encapsulation layer. The planarization layer includes hexamethyldisiloxane.

### BACKGROUND OF INVENTION

### Field of Invention

The present application relates to the field of display devices, and particularly to a display panel and a method for manufacturing the display panel.

### Description of Prior Art

In flat panel display technology, organic light-emitting diode (OLED) displays include many excellent features such as being light and thin, active luminescence, fast response speed, wide viewing angles, wide color gamut, high brightness, low power consumption and an ability to be fabricated as flexible screens, thereby being of great interest to scientific research and industry and gradually becoming the third generation of display technology after liquid crystal displays (LCD).

Nowadays, the “full screen” design has become the mainstream of the times, and all suppliers are focusing on the research and development of full-screen products with a relatively high screen ratio. For example, the IPHONE X mobile phone adopts a notch screen design, and the screen ratio can achieve 81.15%. The recently emerging under-screen camera design is an O-Cut screen design, which cuts an “O”-shaped slot in the display panel for placing the camera. Compared with the notch design, the O-Cut design is closer to the full screen effect. The size of the O-Cut area only needs to consider the front camera. Therefore, the O-Cut area is much smaller than the ratio of the notch area to the entire panel. The advantage of the full screen designed with O-Cut is more obvious, so it has a great advantage in the mobile phone display screen market.

Although the O-Cut design is closer to the full screen, it also faces technical difficulties, and it is particularly difficult to implement the O-Cut design in an OLED flexible display. At present, processes for manufacturing the OLED panel is roughly as follow steps: firstly, a flexible base substrate is produced, then thin film transistors (TFT), an array layer, an OLED layer and a film encapsulation layer are sequentially disposed on the flexible base substrate, and finally, an O-Cutting process is employed using laser to cut holes. In the Active Area (AA) of the panel, an “O”-shaped region is cut to form an “O”-shaped groove for placing the camera. For the O-Cut region, although the devices and wiring of the array region can be avoided, in the OLED manufacturing process, the hole injection layer, the hole transport layer, the light emitting layer, the electron transport layer, the electron injection layer, the cathode layer, and so on, are formed by an evaporation process with an open mask. After cutting the O-Cut region, the cutting region will inevitably affect the integrity of the film encapsulation layer. At this time, water vapor will infiltrate from this position, thereby making the panel lose its functionality. In order to improve the water-blocking function of the panel, a raised structure is usually disposed in the O-Cut region in the prior art, relying on a mushroom-shaped special structure formed by an upper width of the raised structure being larger than the lower width of the raised structure; hence, the edges of the OLED layer are not coherent in the O-Cut region, and the film encapsulation layer is coherent, so as to realize the lateral encapsulation of the HIA (hole in active) region.

Directly preparing a touch function layer above the encapsulation film layer is the current mainstream practice to make device thin and flexible. However, in O-Cut type OLED display components, there is a mushroom-shaped raised structure in the O-Cut region, which is a concave shape. The region is uneven, so the metal line in the touch function layer above the region has a great risk of short circuiting due to over-etching. At the same time, metal is easily left in the groove, and cracks are easily generated during the subsequent cutting process. In view of the coatability of the photoresist, organic photoresist can be coated on the O-Cut region for planarization. However, there is a plurality of concave-convex structures, which are closed ring structures. When coating organic matter, gas is easy to accumulate inside the uneven structures, resulting in some of the uneven structure that cannot be coated. There are still metal residue in the touch function layer in the uncoated area, and cracks is easy generated in the cutting process.

### SUMMARY OF INVENTION

The present application provides a display panel and a method for manufacturing the display panel to solve the problem that the organic photoresist cannot be coated on a part of the structure due to gas easily accumulated inside the space structure of the panel when the planarization layer is formed in the prior art. The uncoated area is prone to metal residues in the touch function layer, and it is easy to produce cracks during cutting.

In order to achieve the above objectives, the present application provides a display panel, the display panel includes a functional region and a display region surrounding the functional region, wherein the functional region includes a light transmission region.

The display panel includes a substrate, at least one raised structure, a film encapsulation layer, and a planarization layer. The substrate is entirely disposed in the display region and the functional region. The raised structure is disposed on the substrate, the raised structure is arranged in the functional region and surrounds the light transmission region, and a space is defined between the raised structure and the display region. The film encapsulation layer covers the substrate, the raised structure, and a space sidewall of the space. The planarization layer is disposed on the film encapsulation layer and filled into the space. The planarization layer includes hexamethyldisiloxane.

Further, the planarization layer includes a first filling layer and a second filling layer. The first filling layer is disposed on the film encapsulation layer. The second filling layer disposed on the first filling layer. The first filling layer includes hexamethyldisiloxane, and the second filling layer includes organic material.

Further, the raised structure includes a first layer and a second layer. The first layer is disposed on the substrate. The second layer is disposed on the first layer. A width of the first layer is less than a width of the second layer.

Further, the film encapsulation layer includes a first barrier layer, a buffer layer, and a second barrier layer. The first barrier layer covers the substrate and the raised structure. The buffer layer is disposed on the first barrier layer and surrounding the functional region. The second barrier layer covers the first barrier layer and the buffer layer. The second barrier layer includes at least one of hexamethyldisiloxane and organic material.

Further, the display panel also includes a touch layer and a light hole. The touch layer is disposed on the planarization layer. The light hole penetrates the display panel corresponding to the light transmission region.

The present application also provides a method for manufacturing a display panel including steps of: preparing a substrate, wherein a raised structure is disposed on the substrate; disposing a film encapsulation layer on the substrate and the raised structure; and disposing a planarization layer on the film encapsulation layer. Material of the planarization layer comprises oxygen-containing gas, hexamethyl dimethyl silyl ether, and silicon tetrafluoride.

Further, when a gas flow of the oxygen-containing gas is less than a gas flow of the hexamethyl dimethyl silyl ether, and a ratio of a gas flow of the silicon tetrafluoride and the gas flow of the hexamethyl dimethyl silyl ether ranges from 0.5 to 1.5, the step of disposing the planarization layer on the film encapsulation layer includes steps of: inputting the oxygen-containing gas, the hexamethyl dimethyl silyl ether, and the silicon tetrafluoride by a chemical vapor deposition process to dispose and form a first filling layer on the film encapsulation layer; and forming a second filling layer on the first filling layer by a coating process or an inkjet printing process.

Further, when a gas flow of the oxygen-containing gas is twice or more than a gas flow of the hexamethyl dimethyl silyl ether, the steps of disposing the planarization layer on the film encapsulation layer includes steps of: inputting the oxygen-containing gas, the hexamethyl dimethyl silyl ether, and the silicon tetrafluoride by a chemical vapor deposition process to dispose and form the planarization layer.

Further, the step of disposing the film encapsulation layer on the organic light emitting device layer and the raised structure includes steps of: disposing a first barrier layer on the organic light emitting device layer and the raised structure by a chemical vapor deposition process; disposing a buffer layer on a part of the first barrier layer; and disposing a second barrier layer on the buffer layer and the first barrier layer by a chemical vapor deposition process; wherein material the second barrier layer comprises at least one of oxygen-containing gas, hexamethyl dimethyl silyl ether, silicon tetrafluoride, and organic material.

Further, when the material the second barrier layer includes the oxygen-containing gas, the hexamethyl dimethyl silyl ether, and the silicon tetrafluoride, a ratio of a gas flow of the oxygen-containing gas and a gas flow of the hexamethyl dimethyl silyl ether is less than 2.

The advantages of the present application are: a display panel and a method for manufacturing the display panel of the present application prepare a planarization layer with hexamethyldisiloxane material by a chemical vapor deposition process, the chemical vapor deposition process can prevent uneven filling caused by gas accumulation, so that the touch layer can be uniformly prepared, to prevent metal residues, and cracks is not generated by a laser cutting process. At the same time, hexamethyldisiloxane material is more flexible than organic material, which can improve the panel bending performance, and also can reduce the amount of organic material and reduce production costs.

### BRIEF DESCRIPTION OF DRAWINGS

In order to more clearly describe the technical solutions of the present invention, the following will briefly introduce the accompanying drawings needed in the description of the embodiments. Obviously, the accompanying drawings in the following description are only some embodiments of the present invention. For those skilled in the art, without creative work, other drawings can be obtained based on these drawings.

FIG. 1 is a layer structural diagram of a display panel of embodiment 1 according to the present application.

FIG. 2 is a layer structural diagram of a raised structure of embodiments 1-3 according to the present application.

FIG. 3 is a flow chart of a manufacturing method of embodiments 1-3 according to the present application.

FIG. 4 is a layer structural diagram after a step S10 of embodiments 1-3 according to the present application.

FIG. 5 is a layer structural diagram after a step S20 of embodiments 1-3 according to the present application.

FIG. 6 is a layer structural diagram after a step S30 of embodiment 1 according to the present application.

FIG. 7 is a layer structural diagram after a step S40 of embodiment 1 according to the present application.

FIG. 8 is a layer structural diagram of a display panel of embodiments 2-3 according to the present application.

FIG. 9 is a layer structural diagram after a step S30 of embodiments 2-3 according to the present application.

FIG. 10 is a layer structural diagram after a step S40 of embodiments 2-3 according to the present application.

Components in the figures are referred to as follows:
display panel 100;
display region 101; functional region 102; light transmission region 103;
substrate 10;
base layer 11; thin film transistor layer 12; organic light emitting layer 13;
raised structure 20;
first layer 21; second layer 22; space 23;
film encapsulation layer 30;
first barrier layer 31; buffer layer 32; second barrier layer 33;
planarization layer 40;
first filling layer 41; second filling layer 42;
touch layer 50; light hole 60.

### DETAILED DESCRIPTION OF PREFERRED EMBODIMENTS

The following describes preferred embodiments of the present invention with reference to the drawings in the specification, to prove that the present invention can be implemented, the embodiments of the invention can fully introduce the present invention to those skilled in the art, making its technical content clearer and easier to understand. The invention can be embodied by many different forms of invention embodiments, and the protection scope of the present invention is not limited to the embodiments mentioned in the text.

In the drawings, components with the same structure are represented by the same numerals, and components with similar structures or functions everywhere are represented by similar numerals. The size and thickness of each component shown in the drawings are arbitrarily shown. The present invention does not limit the size and thickness of each component. In order to make the illustration clearer, the thickness of the parts is appropriately exaggerated in some places in the drawings.

In addition, the following descriptions of the embodiments of the invention refer to the attached drawings to illustrate specific embodiments of the invention that the invention can be implemented. Directional terms mentioned in the invention, for example, “up”, ” “down”, “front”, “back”, “left”, “right”, “inner”, “outer”, “side”, etc., only refer to the directions of the attached drawings. Therefore, the direction terms used are for to explain and understand the present invention more clearly, rather than indicating or implying that the device or element referred to must include a specific orientation, be constructed and operated in a specific orientation, and therefore cannot be understood as a limitation of the present invention. In addition, the term “first”, ” “second”, and “third”, etc. are only used for descriptive purposes, and cannot be understood as indicating or implying relative importance.

When certain components are described as being “on” another component, the component may be directly placed on the other component; there may also be an intermediate component, and the component is placed on the intermediate component, and the intermediate component is placed on another component. When a component is described as “installed to” or “connected to” another component, the two can be understood as directly “installed” or “connected”, or a component indirectly “installed” or “connected” to another component through an intermediate component.

### Embodiment 1

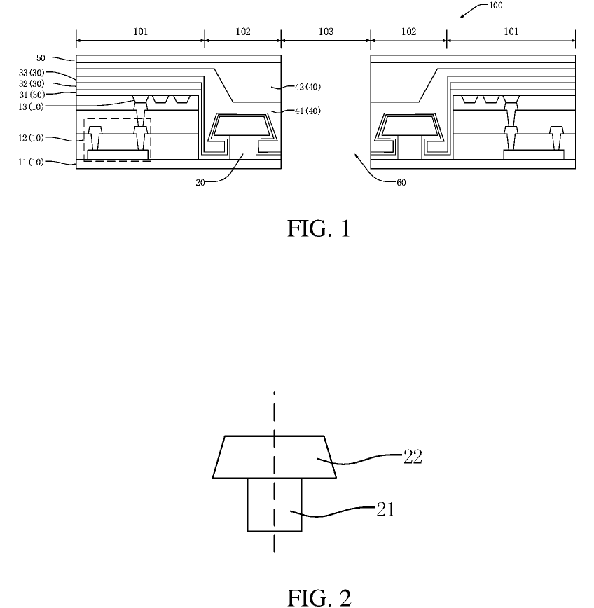

The present application provides a display panel 100. Referring to FIG. 1, a display panel 100 includes a display region 101 and a functional region 102; the display region 101 surrounds the functional region 102. The functional region 102 also includes a light transmission region 103, and the functional region 102 surrounds the light transmission region 103.

Referring to FIG. 1, the display panel 100 includes a substrate 10, a raised structure 20, a film encapsulation layer 30, a planarization layer 40, and a touch layer 50.

The substrate 10 covers the display region 101 and the functional region 102. The substrate 10 includes a base layer 11, a thin film transistor layer 12, and an organic light emitting layer 13. The base layer 11 extends from the display region 101 to the functional region 102, which can use flexible base material, such as polyimide (PI). The display panel 100 realizes the flexible bending display according to the properties of the material used in the base layer 11. The base layer 11 is mainly used to protect the device structure in the display panel 100. The thin film transistor layer 12 is disposed on a surface of the base layer 11, and is located in the display region 101. A plurality of thin film transistors are arranged in the thin film transistor layer 12, and the thin film transistors are used to control to turn on and turn off the organic light emitting layer 13. The organic light emitting layer 13 is disposed on a surface of the thin film transistor layer 12 away from the surface of the base layer 11, and is located in the display region 101. The organic light emitting layer 13 includes a plurality of OLED display components. Each OLED display component is connected to the source and drain electrodes of the thin film transistors, and the current and the voltage are delivered through the thin film transistors for emitting light, thereby forming images on a display screen.

The raised structure 20 is disposed on the base layer 11 and is located in the functional region 102. The raised structure 20 includes a first layer 21 and a second layer 22. The first layer 21 is disposed on the base layer 11, and the second layer 22 is disposed on the first layer 21. A width of the first layer 21 is less than a width of a surface of the second layer 22 close to the first layer 21. Also, Referring to FIG. 2, a center line of the first layer 21 coincides with a center line of the second layer 22, thereby forming a “T” shape structure. A space 23 is defined between the raised structure 20 and the thin film transistor layer 12 and the organic light emitting layer 13 of the substrate 10, and the space 23 is used to block a connection between the raised structure 20 and the thin film transistor layer 12 and the organic light emitting layer 13. The raised structure 20 is used for breaking a coherent structure of the organic light emitting layer 13 formed by an by inkjet printing process to make the film encapsulation layer 30 encapsulate a side of the organic light emitting layer 13 facing the light transmission region 103, thereby preventing water vapor from intruding from the side of the organic light emitting layer 13 and improving the service life of the display panel 100.

The film encapsulation layer 30 covers the organic light emitting layer 13 and the raised structure 20 of the substrate 10. The film encapsulation layer 30 includes a first barrier layer 31, a second barrier layer 33 and a buffer layer 32. The first barrier layer 31 is disposed on the organic light emitting layer 13 and the raised structure 20 and also covers a space 23 wall of the space 23. The buffer layer 32 is disposed on a surface of the first barrier layer 31 away from the substrate 10, and is located in the display region 101, while surrounding the functional region 102. The second barrier layer 33 is disposed on the first barrier layer 31 and covers the buffer layer 32. Among them, the first barrier layer 31 and the second barrier layer 33 are made of organic material, and the buffer layer 32 is made of inorganic material. The film encapsulation layer 30 is used to protect the thin film transistor layer 12 and the organic light emitting layer 13 of the substrate 10 to prevent water and oxygen from intruding and corroding.

The planarization layer 40 is provided on a surface of the film encapsulation layer 30 away from the substrate 10, which includes a first filling layer 41 and a second filling layer 42. The first filling layer 41 is disposed on the second barrier layer 33 of the film encapsulation layer 30 and fills the space 23 to initially flatten the surface of the film encapsulation layer 30. The second filling layer 42 is disposed on the first filling layer 41, which completely flattens the surface of the film encapsulation layer 30. Among them, the first filling layer 41 includes hexamethyldisiloxane (pp-HMDSO), and the second filling layer 42 includes an organic material. The first filling layer 41 can be deposited by a chemical vapor deposition process to form plasma-polymerized hexamethyldisiloxane, which can be prepared by the chemical vapor deposition process so that the gas accumulated in space 23 will not affect its deposition effect, and which is better for filling the space 23 compared with a preparation method of a coating process or an inkjet printing process in the prior art. Additionally, hexamethyldisiloxane is more flexible than organic material, which can improve bending performance of the display panel 100.

The touch layer 50 is disposed on a surface of the planarization layer 40 away from the film encapsulation layer 30, and is arranged with a number of metal lines, which are used to help the display panel 100 realize touch control.

The display panel 100 also includes a light hole 60, and the light hole 60 corresponds to the light transmission region 103 and penetrates the display panel 100. The raised structure 20 surrounds the light hole 60. The light hole 60 is used to provide a light channel for the under-screen camera equipment.

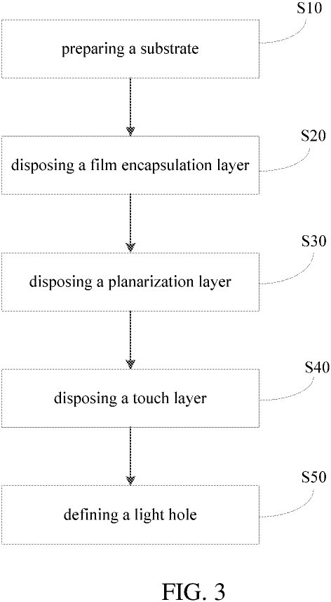

The embodiment of the present application also provides a method for manufacturing the above-mentioned display panel 100, the preparation process of which is shown in FIG. 3, which includes the following steps:

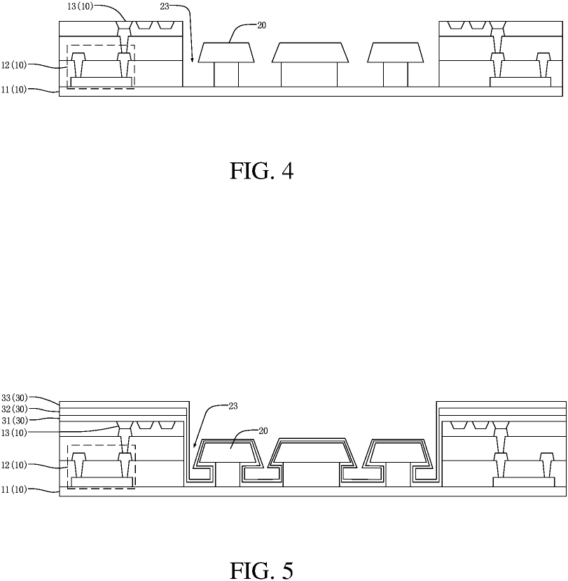

A Step S10 of preparing the substrate 10. The substrate 10 includes a functional region 102 and a display region 101 surrounding the functional region 102. The functional region 102 also includes a light transmission region 103. A base layer 11 is provided, and the base layer 11 covers the display region 101, the functional region 102, and the light transmission region 103. A thin film transistor layer 12 is formed on the base layer 11 in the display region 101 through a thin film transistor manufacturing process. In the thin film transistor manufacturing process, the raised structures 20 in the functional region 102 and the light transmission region 103 are prepared at the same time. Then, an organic light emitting layer 13 is formed on the thin film transistor layer 12 through an inkjet printing process, and finally a layer structure is obtained as shown in FIG. 4.

A step S20 of forming the film encapsulation layer 30. Referring to FIG. 5, a layer of organic material is deposited on the organic light emitting layer 13 and the raised structure 20 of the substrate 10 through a chemical vapor deposition process to form a first barrier layer 31. The first barrier layer 31 covers the space 23 wall of the space 23 between the raised structure 20 and its adjacent structures. A layer of inorganic material is deposited by a chemical vapor deposition process on the first barrier layer 31 in the display region 101 to form a buffer layer 32. A layer of organic material is deposited on the first barrier layer 31 again through a chemical vapor deposition process to form a second barrier layer 33. The second barrier layer 33 covers the buffer layer 32, and the first barrier layer 31, the buffer layer 32, and the second barrier layer 33 are combined to form the film encapsulation layer 30.

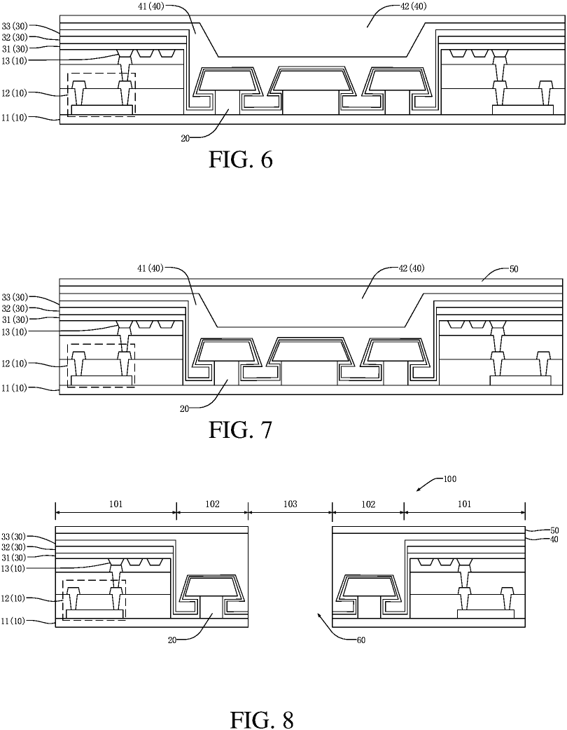

A step S30 of forming the planarization layer 40. Referring to FIG. 6, oxygen-containing gas, hexamethyl dimethyl silyl ether (HMDSO) gas and silicon tetrafluoride gas are introduced into a deposition chamber through a chemical vapor deposition process. A layer of hexamethyldisiloxane material is deposited on the surface of the film encapsulation layer 30 away from the substrate 10 to form the first filling layer 41 after the above-mentioned gases are reacted. Among them, a ratio of a gas flow of the oxygen-containing gas to a gas flow of hexamethyl dimethyl silyl ether is less than 1, and a ratio of a gas flow of silicon tetrafluoride to the gas flow of hexamethyl dimethyl silyl ether is 0.5-1.5. The first filling layer 41 fills the space 23 between the raised structure 20 and its adjacent structures and initially flattens the surface of the film encapsulation layer 30. Through a coating process or through an inkjet printing process, a layer of organic material is deposited on a surface of the first filling layer 41 away from the film encapsulation layer 30 to form the second filling layer 42. The second filling layer 42 flattens the surface of the film encapsulation layer 30 twice. The first filling layer 41 and the second filling layer 42 are combined to form the planarization layer 40.

A step S40 of forming the touch layer 50. Referring to FIG. 7, a layer of metal lines is prepared on the surface of the planarization layer 40 away from the film encapsulation layer 30 by an exposure and etching process to form the touch layer 50.

A step S50 of defining a light hole 60. The display panel 100 located in the light transmission region 103 is cut and removed by a laser cutting process to define the light hole 60, and finally the display panel 100 as shown in FIG. 1 is formed.

A display panel 100 of the present application prepare a planarization layer 40 with hexamethyldisiloxane material through a chemical vapor deposition process. The chemical vapor deposition process can prevent uneven filling caused by gas accumulation, so that the touch layer 50 can be uniformly prepared to prevent metal residues, and cracks are not easily generated by a laser cutting process. At the same time, hexamethyldisiloxane material is more flexible than organic material, which can improve panel bending performance and can also reduce the amount of organic material and reduce production costs.

### Embodiment 2

The present application provides a display panel 100. Referring to FIG. 8, the display panel 100 includes a display region 101 and a functional region 102. The display region 101 surrounds the functional region 102. The functional region 102 also includes a light transmission region 103, and the functional region 102 surrounds the light transmission region 103.

Referring to FIG. 8, the display panel 100 includes a substrate 10, a raised structure 20, a film encapsulation layer 30, a planarization layer 40, and a touch layer 50.

The substrate 10 covers the display region 101 and the functional region 102. The substrate 10 includes a base layer 11, a thin film transistor layer 12, and an organic light emitting layer 13. The base layer 11 extends from the display region 101 to the functional region 102, which can use flexible base material, such as polyimide (PI). The display panel 100 realizes the flexible bending display according to the properties of the material used in the base layer 11. The base layer 11 is mainly used to protect device structure in the display panel 100. The thin film transistor layer 12 is disposed on a surface of the base layer 11 and is located in the display region 101. A plurality of thin film transistors are arranged in the thin film transistor layer 12, and the thin film transistors are used to control to turn on and turn off the organic light emitting layer 13. The organic light emitting layer 13 is disposed on a surface of the thin film transistor layer 12 away from the base layer 11 and is located in the display region 101. The organic light emitting layer 13 includes a plurality of OLED display components. Each OLED display component is connected to the source and drain electrodes of the thin film transistors, and the current and the voltage are delivered through the thin film transistors for emitting light, and then forming a display screen.

The raised structure 20 is disposed on the base layer 11 and is located in the functional region 102. The raised structure 20 includes a first layer 21 and a second layer 22. The first layer 21 is disposed on the base layer 11, and the second layer 22 is disposed on the first layer 21. A width of the first layer 21 is less than a width of a surface of the second layer 22 close to the first layer 21. Also, Referring to FIG. 2, a center line of the first layer 21 coincides with a center line of the second layer 22, thereby forming a “T” shape structure. A space 23 is defined between the raised structure 20 and the thin film transistor layer 12 and the organic light emitting layer 13 of the substrate 10, and the space 23 is used to block a connection between the raised structure 20, the thin film transistor layer 12, and the organic light emitting layer 13. The raised structure 20 is used for breaking a coherent structure of the organic light emitting layer 13 formed by an inkjet printing process to make the film encapsulation layer 30 encapsulate a side of the organic light emitting layer 13 facing the light transmission region 103, thereby preventing water vapor from intruding from the side of the organic light emitting layer 13 and improving the service life of the display panel 100.

The film encapsulation layer 30 covers the organic light emitting layer 13 and the raised structure 20 of the substrate 10. The film encapsulation layer 30 includes a first barrier layer 31, a second barrier layer 33, and a buffer layer 32. The first barrier layer 31 is disposed on the organic light emitting layer 13 and the raised structure 20, and also covers a space 23 wall of the space 23. The buffer layer 32 is disposed on a surface of the first barrier layer 31 away from the substrate 10 and is located in the display region 101, while surrounding the functional region 102. The second barrier layer 33 is disposed on the first barrier layer 31 and covers the buffer layer 32. Among them, the first barrier layer 31 and the second barrier layer 33 are made of organic material, and the buffer layer 32 is made of inorganic material. The film encapsulation layer 30 is used to protect the thin film transistor layer 12 and the organic light emitting layer 13 of the substrate 10 to prevent water and oxygen from intruding and corroding.

The planarization layer 40 is provided on a surface of the film encapsulation layer 30 away from the substrate 10, fills the space 23 between the raised structure 20 and its adjacent structures, and flattens the surface of the film encapsulation layer 30. The planarization layer 40 includes hexamethyldisiloxane (pp-HMDSO), which can be deposited through a chemical vapor deposition process to form plasma-polymerized hexamethyldisiloxane, which can be prepared by the chemical vapor deposition process so that gas accumulated in space 23 will not affect the deposition effect of the planarization 40, and which is better for filling the space 23 compared with a preparation method of a coating process or an inkjet printing process in the prior art. Additionally, hexamethyldisiloxane is more flexible than organic material, which can improve bending performance of the display panel 100.

The touch layer 50 is disposed on a surface of the planarization layer 40 away from the film encapsulation layer 30 and is arranged with a number of metal lines, which are used to help the display panel 100 realize touch control.

The display panel 100 also includes a light hole 60; the light hole 60 corresponds to the light transmission region 103 and penetrates the display panel 100. The raised structure 20 surrounds the light hole 60. The light hole 60 is used to provide a light channel for the under-screen camera equipment.

The embodiment of the present application also provides a method for manufacturing the above-mentioned display panel 100, the preparation process is shown in FIG. 3, which includes the following steps:

A Step S10 of preparing the substrate 10. The substrate 10 includes a functional region 102 and a display region 101 surrounding the functional region 102. The functional region 102 also includes a light transmission region 103. A base layer 11 is provided, and the base layer 11 covers the display region 101, the functional region 102, and the light transmission region 103. A thin film transistor layer 12 is formed on the base layer 11 in the display region 101 through a thin film transistor manufacturing process. In the thin film transistor manufacturing process, the raised structures 20 in the functional region 102 and the light transmission region 103 are prepared at the same time. Then, an organic light emitting layer 13 is formed on the thin film transistor layer 12 by an inkjet printing process, and finally a layer structure is obtained as shown in FIG. 4.

A step S20 of forming the film encapsulation layer 30. Referring to FIG. 5, a layer of organic material is deposited on the organic light emitting layer 13 and the raised structure 20 of the substrate 10 by a chemical vapor deposition process to form a first barrier layer 31. The first barrier layer 31 covers the space 23 wall of the space 23 between the raised structure 20 and its adjacent structures. A layer of inorganic material is deposited through a chemical vapor deposition process on the first barrier layer 31 in the display region 101 to form a buffer layer 32. A layer of organic material is deposited on the first barrier layer 31 again through a chemical vapor deposition process to form a second barrier layer 33. The second barrier layer 33 covers the buffer layer 32 and the first barrier layer 31. The buffer layer 32 and the second barrier layer 33 are combined to form the film encapsulation layer 30.

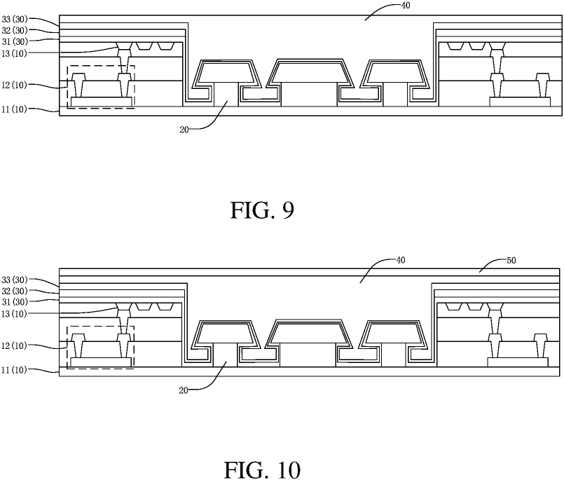

A step S30 of forming the planarization layer 40. Referring to FIG. 9, oxygen-containing gas, hexamethyl dimethyl silyl ether (HMDSO) gas and silicon tetrafluoride gas are introduced into the deposition chamber through a chemical vapor deposition process. A layer of hexamethyldisiloxane material is deposited on the surface of the film encapsulation layer 30 away from the substrate 10 to form the planarization layer 40 after the above-mentioned gas are reacted. Among them, a gas flow of the oxygen-containing gas is twice or more than a gas flow of the hexamethyl dimethyl silyl ether. The planarization layer 40 fills the space 23 between the raised structure 20 and its adjacent structures and flattens the surface of the film encapsulation layer 30.

A step S40 of forming the touch layer 50. Referring to FIG. 10, a layer of metal lines is prepared on a surface of the planarization layer 40 away from the film encapsulation layer 30 through an exposure and etching process to form the touch layer 50.

A step S50 of defining the light hole 60. The display panel 100 located in the light transmission region 103 is cut and removed through a laser cutting process to define the light hole 60, and finally the display panel 100 as shown in FIG. 1 is formed.

A display panel 100 is provided in the present application. The planarization layer 40 is prepared by adjusting a gas flow ratio between oxygen-containing gas and hexamethyl dimethyl silyl ether, thereby changing the film quality of the planarization layer 40 including hexamethyldisiloxane formed by deposition. The planarization layer 40 made of hexamethyldisiloxane material completely fills and flattens the surface of the film encapsulation layer 30. In this embodiment, the planarization layer 40 made of organic material can be completely eliminated, the preparation method is simpler, and the amount of organic material can also be further reduced, thereby reducing production costs.

### Embodiment 3

The present application provides a display panel 100. Referring to FIG. 8, the display panel 100 includes a display region 101 and a functional region 102. The display region 101 surrounds the functional region 102. The functional region 102 also includes a light transmission region 103, and the functional region 102 surrounds the light transmission region 103.

Referring to FIG. 8, the display panel 100 includes a substrate 10, a raised structure 20, a film encapsulation layer 30, a planarization layer 40, and a touch layer 50.

The substrate 10 covers the display region 101 and the functional region 102. The substrate 10 includes a base layer 11, a thin film transistor layer 12, and an organic light emitting layer 13. The base layer 11 extends from the display region 101 to the functional region 102, which can use flexible base material, such as polyimide (PI). The display panel 100 realizes flexible bending display according to the properties of the material used in the base layer 11. The base layer 11 is mainly used to protect the device structure in the display panel 100. The thin film transistor layer 12 is disposed on a surface of the base layer 11 and is located in the display region 101. A plurality of thin film transistors are arranged in the thin film transistor layer 12, and the thin film transistors are used to control to turn on and turn off the organic light emitting layer 13. The organic light emitting layer 13 is disposed on a surface of the thin film transistor layer 12 away from the base layer 11 and is located in the display region 101. The organic light emitting layer 13 includes a plurality of OLED display components. Each OLED display component is connected to the source and drain electrodes of the thin film transistors, and the current and the voltage are delivered through the thin film transistors for emitting light, thereby forming images on a display screen.

The raised structure 20 is disposed on the base layer 11 and is located in the functional region 102. The raised structure 20 includes a first layer 21 and a second layer 22. The first layer 21 is disposed on the base layer 11, and the second layer 22 is disposed on the first layer 21. A width of the first layer 21 is less than a width of a surface of the second layer 22 close to the first layer 21. Also, Referring to FIG. 2, a center line of the first layer 21 coincides with a center line of the second layer 22, thereby forming a “T” shape structure. A space 23 is defined between the raised structure 20 and the thin film transistor layer 12 and the organic light emitting layer 13 of the substrate 10, and the space 23 is used to block a connection between the raised structure 20, and the thin film transistor layer 12 and the organic light emitting layer 13. The raised structure 20 is used for breaking a coherent structure of the organic light emitting layer 13 formed by an by inkjet printing process to make the film encapsulation layer 30 encapsulate a side of the organic light emitting layer 13 facing the light transmission region 103, thereby preventing water vapor from intruding from the side of the organic light emitting layer 13 and improving the service life of the display panel 100.

The film encapsulation layer 30 covers the organic light emitting layer 13 and the raised structure 20 of the substrate 10. The film encapsulation layer 30 includes a first barrier layer 31, a second barrier layer 33, and a buffer layer 32. The first barrier layer 31 is disposed on the organic light emitting layer 13 and the raised structure 20, and also covers a space 23 wall of the space 23. The buffer layer 32 is disposed on a surface of the first barrier layer 31 away from the substrate 10 and is located in the display region 101, while surrounding the functional region 102. The second barrier layer 33 is disposed on the first barrier layer 31 and covers the buffer layer 32. Among them, the first barrier layer 31 includes organic material, and the buffer layer 32 includes inorganic material. The second barrier layer 33 includes hexamethyldisiloxane. The film encapsulation layer 30 is used to protect the thin film transistor layer 12 and the organic light emitting layer 13 of the substrate 10 to prevent water and oxygen from intruding and corroding.

The planarization layer 40 is provided on a surface of the film encapsulation layer 30 away from the substrate 10, fills a space 23 between the raised structure 20 and its adjacent structures, and flattens the surface of the film encapsulation layer 30. The planarization layer 40 includes hexamethyldisiloxane (pp-HMDSO), which can be deposited through a chemical vapor deposition process to form plasma-polymerized hexamethyldisiloxane, which can be prepared by the chemical vapor deposition process so that the gas accumulated in space 23 will not affect the deposition effect of the planarization layer 40, and which is better for filling the space 23 compared with a preparation method of a coating process or an inkjet printing process in the prior art. Additionally, hexamethyldisiloxane is more flexible than organic material, which can improve bending performance of the display panel 100.

The touch layer 50 is disposed on a surface of the planarization layer 40 away from the film encapsulation layer 30 and is arranged with a number of metal lines, which are used to help the display panel 100 realize touch control.

The display panel 100 also includes a light hole 60. The light hole 60 corresponds to the light transmission region 103 and penetrates the display panel 100. The raised structure 20 surrounds the light hole 60. The light hole 60 is used to provide a light channel for the under-screen camera equipment.

The embodiment of the present application also provides a method for manufacturing the above-mentioned display panel 100, the preparation process for which is shown in FIG. 3, which includes the following steps:

A Step S10 of preparing the substrate 10. The substrate 10 includes a functional region 102 and a display region 101 surrounding the functional region 102. The functional region 102 also includes a light transmission region 103. A base layer 11 is provided, and the base layer 11 covers the display region 101, the functional region 102, and the light transmission region 103. A thin film transistor layer 12 is formed on the base layer 11 in the display region 101 through a thin film transistor process. In the thin film transistor process, the raised structures 20 are prepared in the functional region 102 and the light transmission region 103 at the same time. Then an organic light emitting layer 13 is formed on the thin film transistor layer 12 by an inkjet printing process, and finally a layer structure is obtained as shown in FIG. 4.

A step S20 of forming the film encapsulation layer 30. Referring to FIG. 5, a layer of organic material is deposited on the organic light emitting layer 13 and the raised structure 20 of the substrate 10 through a chemical vapor deposition process to form a first barrier layer 31. The first barrier layer 31 covers the space 23 wall of the space 23 between the raised structure 20 and its adjacent structures. A layer of inorganic material is deposited by a chemical vapor deposition process on the first barrier layer 31 in the display region 101 to form a buffer layer 32. A layer of organic material is deposited on the first barrier layer 31 again through a chemical vapor deposition process to form a second barrier layer 33. the second barrier layer 33 covers the buffer layer 32, and the first barrier layer 31, the buffer layer 32 and the second barrier layer 33 are combined to form the film encapsulation layer 30.

A step S30 of forming the planarization layer 40. Referring to FIG. 9, in the deposition chamber, a gas flow of the oxygen-containing gas is adjusted to twice or more than a gas flow of the hexamethyl dimethyl silyl ether at the same time silicon tetrafluoride gas is being introduced. A layer of hexamethyldisiloxane material is deposited on the surface of the film encapsulation layer 30 away from the substrate 10 to form the planarization layer 40 after the above-mentioned gases are reacted. The planarization layer 40 fills the space 23 between the raised structure 20 and its adjacent structures and flattens the surface of the film encapsulation layer 30.

A step S40 of forming the touch layer 50. Referring to FIG. 10, a layer of metal lines is prepared on the surface of the planarization layer 40 away from the film encapsulation layer 30 by an exposure and etching process to form the touch layer 50.

A step S50 of defining the light hole 60. The display panel 100 located in the light transmission region 103 is cut and removed by a laser cutting process to define the light hole 60, and finally the display panel 100 as shown in FIG. 1 is formed.

A display panel 100 is provided in the present application. The organic material in the second barrier layer 33 in the film encapsulation layer 30 is replaced with hexamethyldisiloxane, and a gas flow ratio of the oxygen-containing gas to the hexamethyl dimethyl silyl ether is adjusted, so a film quality of the second barrier layer 33 is different from a film quality of the planarization layer 40 of a same material. In this embodiment, the organic material in the second barrier layer 33 in the film encapsulation layer 30 is replaced with hexamethyldisiloxane on the basis of Embodiment 2 and is also prepared using a chemical vapor deposition process, allowing it to be prepared with the planarization layer 40 in the same chemical vapor deposition process, thereby reducing a number of chemical vapor deposition processes, further reducing the amount of organic material and reducing production costs.

Although the present invention is described herein with reference to specific embodiments, it should be understood that these embodiments are merely examples of the principles and applications of the present invention. It should therefore be understood that many modifications can be made to the exemplary embodiments, and other arrangements can be devised as long as they do not deviate from the spirit and scope of the invention as defined by the appended claims. It should be understood that different dependent claims and features described herein can be combined in ways different from those described in the original claims. It can also be understood that features described in combination with a single embodiment can be used in other embodiments.

1. A display panel comprising a functional region and a display region surrounding the functional region, wherein the functional region comprises a light transmission region;
the display panel comprises:
a substrate disposed in an entire display region and the functional region;
at least one raised structure disposed on the substrate, wherein the raised structure is arranged in the functional region and surrounds the light transmission region, and a space is defined between the raised structure and the display region;
a film encapsulation layer covering the substrate, the raised structure, and a space sidewall of the space; and
a planarization layer disposed on the film encapsulation layer and filled into the space;
wherein the planarization layer comprises hexamethyldisiloxane.

2. The display panel of claim 1, wherein the planarization layer comprises:
a first filling layer disposed on the film encapsulation layer; and
a second filling layer disposed on the first filling layer;
wherein the first filling layer comprises hexamethyldisiloxane, and the second filling layer comprises organic material.

3. The display panel of claim 1, wherein the raised structure comprises:
a first layer disposed on the substrate; and
a second layer disposed on the first layer;
a width of the first layer is less than a width of the second layer.

4. The display panel of claim 1, wherein the film encapsulation layer comprises:
a first barrier layer covering the substrate and the raised structure;
a buffer layer disposed on the first barrier layer and surrounding the functional region; and
a second barrier layer covering the first barrier layer and the buffer layer;
wherein the second barrier layer comprises at least one of hexamethyldisiloxane or organic material.

5. The display panel of claim 1, further comprising:
a touch layer disposed on the planarization layer; and
a light hole penetrating the display panel and corresponding to the light transmission region.

6. A method for manufacturing a display panel, comprising steps of:
preparing a substrate, wherein an organic light emitting layer and a raised structure are disposed on the substrate;
disposing a film encapsulation layer on the organic light emitting layerand the raised structure; and
disposing a planarization layer on the film encapsulation layer;
wherein material of the planarization layer comprises oxygen-containing gas, hexamethyl dimethyl silyl ether, and silicon tetrafluoride.

7. The method for manufacturing the display panel of claim 6, wherein when a gas flow of the oxygen-containing gas is less than a gas flow of the hexamethyl dimethyl silyl ether, and a ratio of a gas flow of the silicon tetrafluoride to the gas flow of the hexamethyl dimethyl silyl ether ranges from 0.5 to 1.5, the step of disposing the planarization layer on the film encapsulation layer comprises steps of:
inputting the oxygen-containing gas, the hexamethyl dimethyl silyl ether, and the silicon tetrafluoride by a chemical vapor deposition process to dispose and form a first filling layer on the film encapsulation layer; and
forming a second filling layer on the first filling layer by a coating process or an inkjet printing process.

8. The method for manufacturing the display panel of claim 6, wherein when a gas flow of the oxygen-containing gas is twice or more than a gas flow of the hexamethyl dimethyl silyl ether, the steps of disposing the planarization layer on the film encapsulation layer comprises steps of:
introducing the oxygen-containing gas, the hexamethyl dimethyl silyl ether, and the silicon tetrafluoride through a chemical vapor deposition process to dispose and form the planarization layer.

9. The method for manufacturing the display panel of claim 6, wherein the step of disposing the film encapsulation layer on the organic light emitting layer and the raised structure comprises steps of:
disposing a first barrier layer on the organic light emitting layer and the raised structure through a chemical vapor deposition process;
disposing a buffer layer on a part of the first barrier layer; and
disposing a second barrier layer on the buffer layer and the first barrier layer through a chemical vapor deposition process;
wherein material of the second barrier layer comprises at least one of oxygen-containing gas, hexamethyl dimethyl silyl ether, silicon tetrafluoride, or organic material.

10. The method for manufacturing the display panel of claim 9, wherein when the material of the second barrier layer comprises the oxygen-containing gas, the hexamethyl dimethyl silyl ether, or the silicon tetrafluoride, a ratio of a gas flow of the oxygen-containing gas to a gas flow of the hexamethyl dimethyl silyl ether is less than 2.
